(19) United States
(12) Patent Application Publication
(10) Pub. No.: US 2015/0069327 A1
(43) Pub. Date: Mar. 12, 2015

(54) FIN FIELD-EFFECT TRANSISTORS WITH SUPERLATTICE CHANNELS

(71) Applicant: International Business Machines Corporation, Armonk, NY (US)

(72) Inventors: Kangguo Cheng, Schenectady, NY (US); Bruce B. Doris, Slinerlands, NY (US); Pouya Hashemi, White Plains, NY (US); Hong He, Schenectady, NY (US); Ali Khakifirooz, Mountain View, CA (US); Alexander Reznicek, Troy, NY (US)

(73) Assignee: International Business Machines Corporation, Armonk, NY (US)

(21) Appl. No.: 14/023,581

(22) Filed: Sep. 11, 2013

(51) Int. Cl. H01L 29/15; H01L 29/66; H01L 21/02; H01L 21/8234

(52) U.S. Cl. CPC H01L 29/158; H01L 21/823431; H01L 29/66795; H01L 21/02507
USPC 257/19; 438/283

(57) ABSTRACT

FinFET structures may be formed including superlattice fins. The structure may include a superlattice fin of alternating layers of silicon-germanium with a germanium concentration of approximately 10% to 80% and a second semiconductor material. In some embodiments, the second semiconductor material may include either silicon or carbon-doped silicon. Where the second semiconductor material is carbon-doped silicon, the carbon concentration may range from approximately 0.2% to approximately 4%. The superlattice fin may have a height ranging from approximately 5 nm to approximately 100 nm and include between 5 and 30 alternating layers of silicon-germanium and the second semiconductor material. A gate may be formed over the superlattice fin and a source/drain region may be formed over an end of the superlattice fin.

### BACKGROUND

The present invention generally relates to semiconductor devices, and particularly to fin field-effect transistors (FinFETs) having superlattice channels.

FinFETs are an emerging technology which provides solutions to field effect transistor (FET) scaling problems at, and below, the 22 nm node. FinFET structures include at least one narrow semiconductor fin gated on at least two sides of each of the at least one semiconductor fin. FinFET structures may be formed on a semiconductor-on-insulator (SOI) substrate, because of the low source/drain diffusion, low substrate capacitance, and ease of electrical isolation by shallow trench isolation structures.

In a FinFET structure with p-type source/drains and an n-type channel (pFinFET), it may be desirable to make the fin of compressively strained silicon-germanium (SiGe) to improve device performance. However, a SiGe fin will reduce the performance of a FinFET structure with n-type source/drains and a p-type channel (nFinFET). Therefore, nFinFET channels are typically made of silicon without any added germanium.

Further, in a FinFET structure, it may be desirable to make the fin as tall as possible to increase the effective channel width without increasing the footprint of the structure. Because SiGe layers may only be formed to a maximum thickness (the critical thickness) that is less than the potential thickness of a Si layer, the fins of pFinFETs may not be constructed to the same height as those of nFinFETs. Because having fins of different heights may lead to complications later in the fabrication process, a method of forming SiGe fins for pFinFETs of greater than the SiGe critical thickness may be desirable.

### BRIEF SUMMARY

According to one embodiment, a FinFET structure may include a superlattice fin of alternating layers of silicon-germanium and carbon-doped silicon, a gate located adjacent the superlattice fin, and a source/drain region over an end of the superlattice fin.

According to another embodiment, a semiconductor structure may include a superlattice fin on a substrate, where the superlattice fin is made of alternating layers of a first semiconductor material and a second semiconductor material, a gate over the superlattice fin, and a source/drain region over an end of the superlattice fin. The first semiconductor material may be silicon-germanium and the second semiconductor material may be either silicon or carbon-doped silicon.

According to another embodiment, a semiconductor structure may be formed by forming a superlattice of a first semiconductor material and a second semiconductor material, etching the superlattice to form a fin, forming a gate over the fin, and forming a source/drain region over a portion of the fin not covered by the gate. The first semiconductor material may be silicon-germanium and the second semiconductor material may be either silicon or carbon-doped silicon.

### BRIEF DESCRIPTION OF THE SEVERAL VIEWS OF THE DRAWINGS

The following detailed description, given by way of example and not intended to limit the invention solely thereto, will best be appreciated in conjunction with the accompanying drawings, in which:

FIG. 1A is a top view depicting a substrate, according an embodiment of the present invention;

FIG. 1B is a cross-sectional view of the structure of FIG. 1A, along line A-A of FIG. 1A, according to an embodiment of the present invention;

FIG. 1C is a cross-sectional view of the structure of FIG. 1A, along line B-B of FIG. 1A, according to an embodiment of the present invention;

FIG. 2A is a top view depicting forming a superlattice above the substrate of FIGS. 1A-1C, according to an embodiment of the present invention;

FIG. 2B is a cross-sectional view of the structure of FIG. 2A, along line A-A of FIG. 2A, according to an embodiment of the present invention;

FIG. 2C is a cross-sectional view of the structure of FIG. 2A, along line B-B of FIG. 2A, according to an embodiment of the present invention;

FIG. 3A is a top view of forming a fin from the superlattice of FIGS. 2A-2C, according to an embodiment of the present invention;

FIG. 3B is a cross-sectional view of the structure of FIG. 3A, along line A-A of FIG. 3A, according to an embodiment of the present invention;

FIG. 3C is a cross-sectional view of the structure of FIG. 3A, along line B-B of FIG. 3A, according to an embodiment of the present invention;

FIG. 4A is a top view of forming a gate above the fin of FIGS. 3A-3C, according to an embodiment of the present invention;

FIG. 4B is a cross-sectional view of the structure of FIG. 4A, along line A-A of FIG. 4A, according to an embodiment of the present invention;

FIG. 4C is a cross-sectional view of the structure of FIG. 4A, along line B-B of FIG. 4A, according to an embodiment of the present invention;

FIG. 5A is a top view of forming a spacer on the gate of FIGS. 4A-4C, according to an embodiment of the present invention;

FIG. 5B is a cross-sectional view of the structure of FIG. 5A, along line A-A of FIG. 5A, according to an embodiment of the present invention;

FIG. 5C is a cross-sectional view of the structure of FIG. 5A, along line B-B of FIG. 5A, according to an embodiment of the present invention;

FIG. 6A is a top view of forming source/drain regions adjacent to the gate of FIGS. 5A-5C, according an embodiment of the present invention;

FIG. 6B is a cross-sectional view of the structure of FIG. 6A, along line A-A of FIG. 6A, according to an embodiment of the present invention; and

FIG. 6C is a cross-sectional view of the structure of FIG. 6A, along line B-B of FIG. 6A, according to an embodiment of the present invention.

Elements of the figures are not necessarily to scale and are not intended to portray specific parameters of the invention. For clarity and ease of illustration, scale of elements may be exaggerated. The detailed description should be consulted for accurate dimensions. The drawings are intended to depict only typical embodiments of the invention, and therefore should not be considered as limiting the scope of the invention. In the drawings, like numbering represents like elements.

### DETAILED DESCRIPTION

Exemplary embodiments will now be described more fully herein with reference to the accompanying drawings, in which exemplary embodiments are shown. This disclosure may, however, be embodied in many different forms and should not be construed as limited to the exemplary embodiments set forth herein. Rather, these exemplary embodiments are provided so that this disclosure will be thorough and complete and will fully convey the scope of this disclosure to those skilled in the art. In the description, details of well-known features and techniques may be omitted to avoid unnecessarily obscuring the presented embodiments.

References in the specification to “one embodiment”, “an embodiment”, “an example embodiment”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is submitted that it is within the knowledge of one skilled in the art to affect such feature, structure, or characteristic in connection with other embodiments whether or not explicitly described.

For purposes of the description hereinafter, terms such as “upper”, “lower”, “right”, “left”, “vertical”, “horizontal”, “top”, “bottom”, and derivatives thereof shall relate to the disclosed structures and methods, as oriented in the drawing figures. The terms “overlying”, “atop”, “on top”, “positioned on” or “positioned atop” mean that a first element, such as a first structure, is present on a second element, such as a second structure, wherein intervening elements, such as an interface structure may be present between the first element and the second element. The term “direct contact” means that a first element, such as a first structure, and a second element, such as a second structure, are connected without any intermediary conducting, insulating or semiconductor layers at the interface of the two elements.

In the interest of not obscuring the presentation of embodiments of the present invention, in the following detailed description, some processing steps or operations that are known in the art may have been combined together for presentation and for illustration purposes and in some instances may have not been described in detail. In other instances, some processing steps or operations that are known in the art may not be described at all. It should be understood that the following description is rather focused on the distinctive features or elements of various embodiments of the present invention.

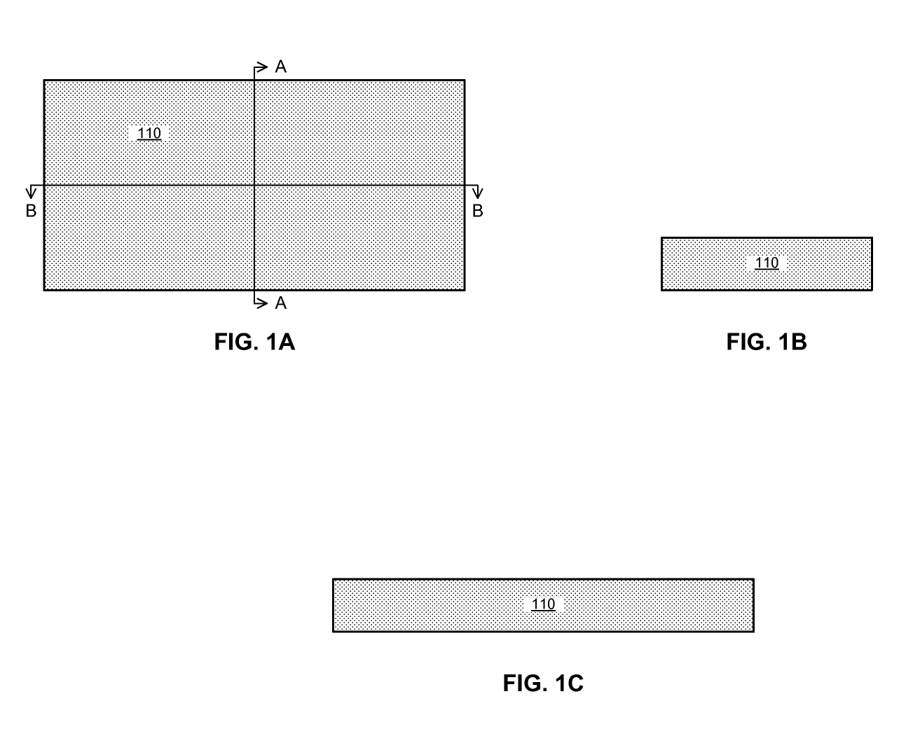

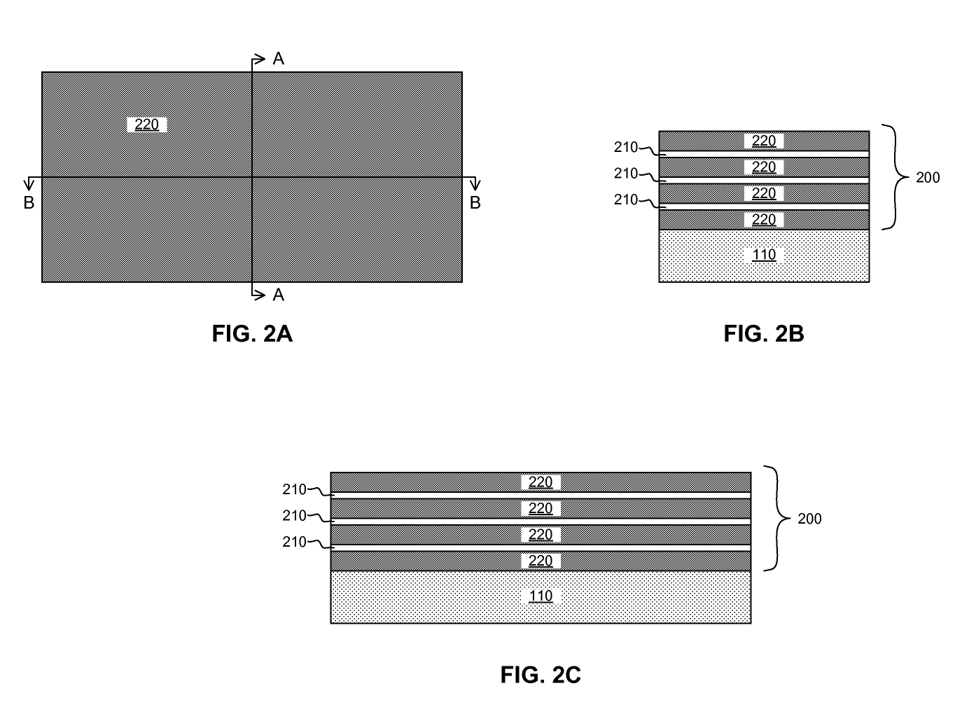

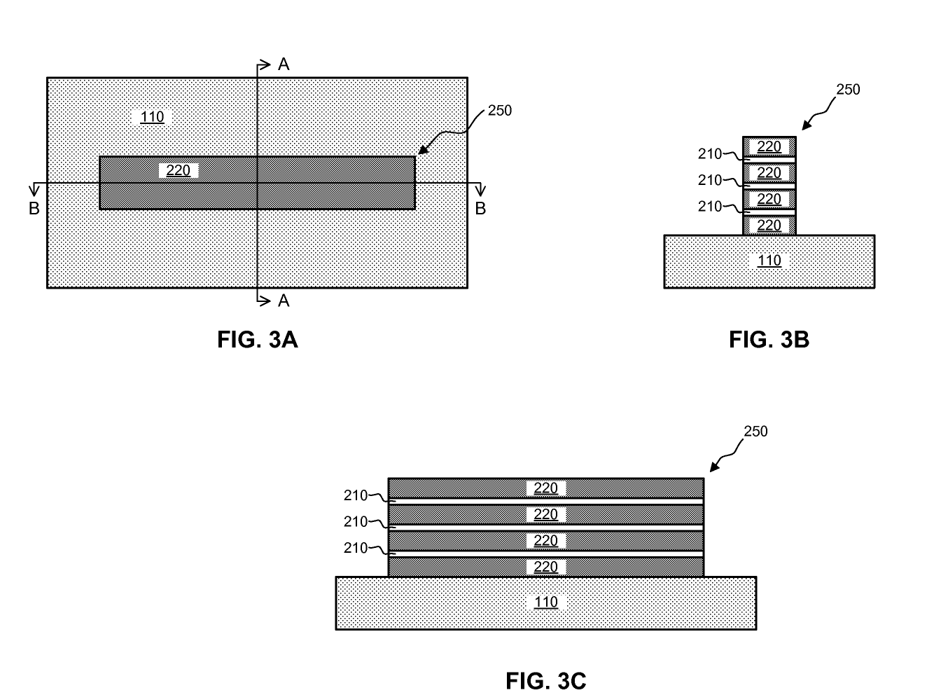

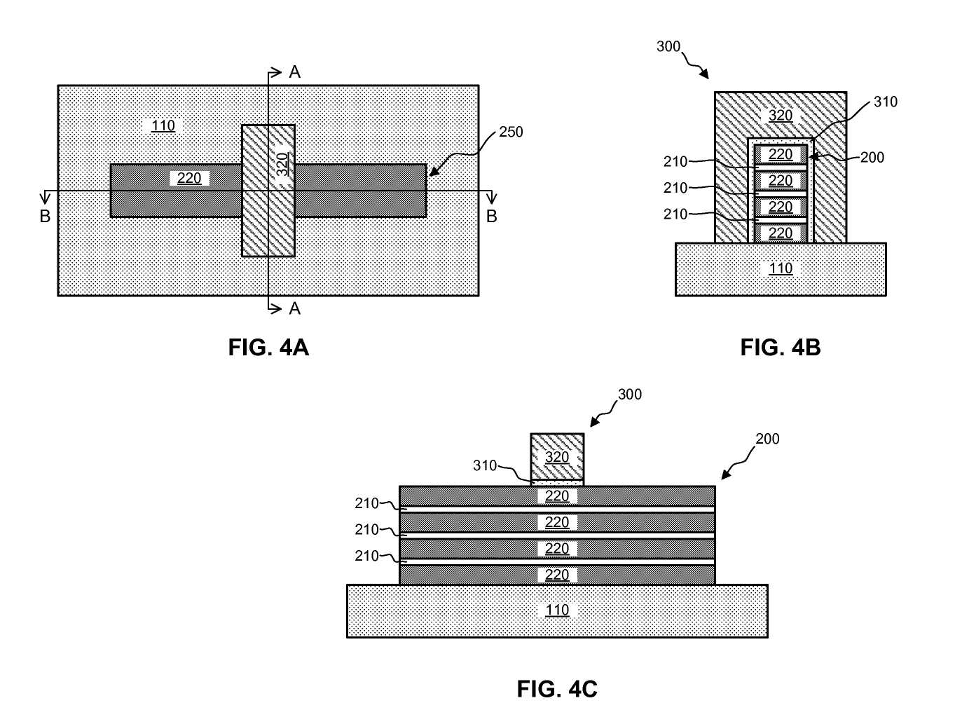

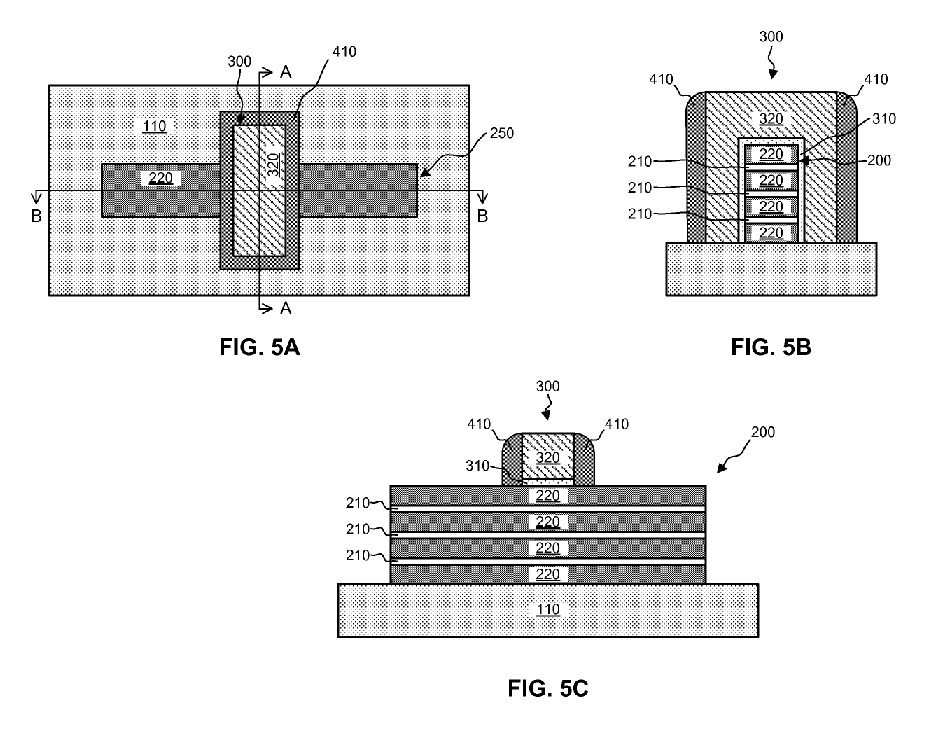

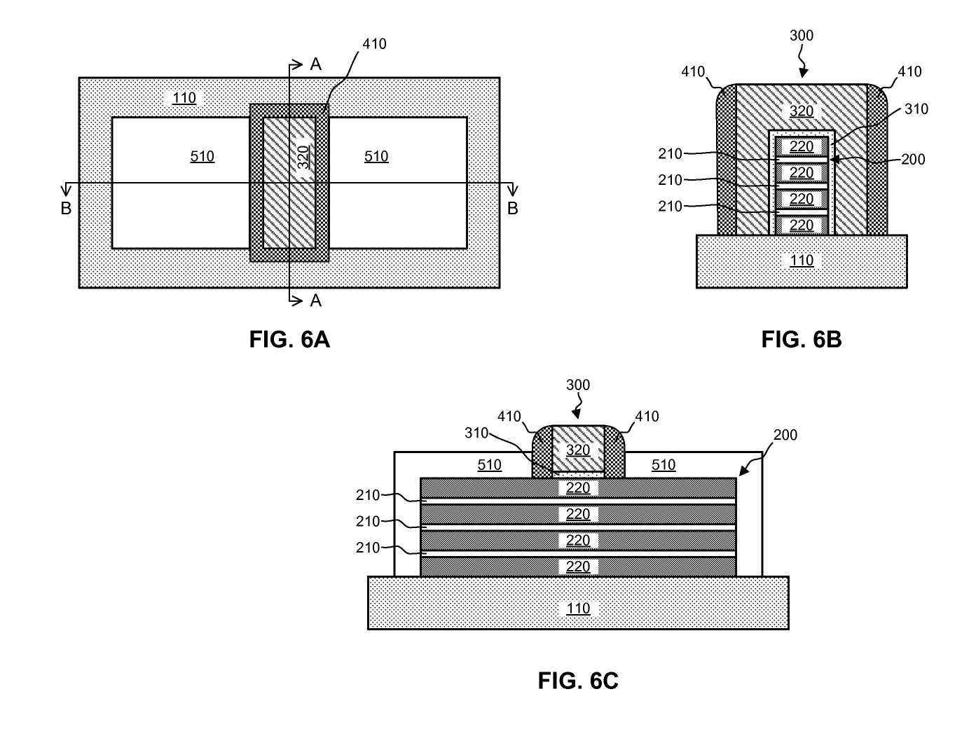

As described below in conjunction with FIGS. 1A-6C, embodiments of the invention generally relate to methods of forming a FinFET device having a superlattice channel. In FIGS. 1A-1C, a substrate 110 may be provided. In FIGS. 2A-2C, a superlattice 200 may be formed above the substrate 110. In FIGS. 3A-3C, the superlattice 200 may be etched to form a fin 250. In FIGS. 4A-4C, a gate 300 may be formed over the fin 250. In FIGS. 5A-5C, a spacer 410 may be formed on sidewalls of the gate 300. In FIGS. 6A-6C, source/drains 510 may be formed over the fin 250 on opposing sides of the gate 300. Figures with the suffix “A” are top down views of an exemplary structure at each step of the fabrication process. Figures with the suffix “B” or “C” are vertical cross-sectional views of the exemplary structure along the plane indicated by line A-A or B-B, respectively, of the corresponding figure with the same numeric label and the suffix “A”.

Referring to FIGS. 1A-1C, a substrate 110 may be provided. The substrate 110 may be made of any material or materials capable of supporting the superlattice structure described below in conjunction with FIGS. 2A-2C. In an exemplary embodiment, the substrate 110 may be a semiconductor-on-insulator (SOI) substrate in an insulating layer above a base, or handle, semiconductor layer (not shown). The base semiconductor layer made from any of several known semiconductor materials such as, for example, silicon, germanium, silicon-germanium alloy, silicon carbide, silicon-germanium carbide alloy, and compound (e.g. III-V and II-VI) semiconductor materials. Non-limiting examples of compound semiconductor materials include gallium arsenide, indium arsenide, and indium phosphide. Typically the base semiconductor layer may be about, but is not limited to, several hundred microns thick. For example, the base semiconductor layer may include a thickness ranging from 0.5 mm to about 1.5 mm.

The insulating layer may be made from any of several known insulator materials. Non-limiting examples include, for example, oxides, nitrides and oxynitrides of silicon. Oxides, nitrides and oxynitrides of other elements are also envisioned. The insulating layer may be crystalline or non-crystalline, and may be formed by any of several known methods, including, but not limited, ion implantation, thermal or plasma oxidation or nitridation, chemical vapor deposition (CVD), physical vapor deposition (PVD), and atomic layer deposition (ALD). The insulating layer may have a thickness ranging from approximately 10 nm to approximately 80 nm. In one embodiment, the insulating layer may have a thickness of approximately 20 nm.

Referring to FIGS. 2A-2C, a superlattice 200 may be formed above the substrate 110. The superlattice 200 may be formed by depositing or growing first semiconductor layers 210 and second semiconductor layers 220 in alternating order. While the superlattice 200 depicted in FIGS. 2A-2C includes a first semiconductor layer 210 as the bottom layer, other embodiments may include a second semiconductor layer 220 first deposited on the substrate 110.

The first semiconductor layers 210 may be made of a silicon-germanium (i.e., SiGe layers 210) alloy with a germanium concentration of approximately 10% to approximately 80%, preferably approximately 20% to approximately 60%. The SiGe layers 210 may be compressively strained if grown pseudomorphically onto the silicon substrate. The second semiconductor layers 220 may be made of silicon or of carbon-doped silicon (i.e., Si:C layers 220) with a carbon concentration of approximately 0.2% to approximately 4%, preferably approximately 0.3% to approximately 2.5%. The carbon-doped silicon layers 220 may be tensilely strained if grown pseudomorphically onto the silicon substrate, as depicted in FIGS. 2B-2C. Higher or lower concentrations of germanium and carbon in the first semiconductor layers 210 and the second semiconductor layers 220, respectively, are explicitly contemplated. Moreover, other layers having the same of similar material properties to that of the SiGe and Si:C may be employed in the formation of superlattice 200.

In some embodiments, the superlattice 200 may comprise between 5 and 30 layers (i.e. the sum of all first semiconductor layers 210 and second semiconductor layers 220), depending on the thickness of the individual layers and the desired fin height. Typically, pFinFETs are constructed with fins having a height of approximately 5 nm to approximately 100 nm, preferably approximately 10 nm to approximately 60 nm. Therefore, the superlattice 200 may have a thickness in approximately the same range. In some embodiments, this thickness of the first semiconductor layers 210 may be approximately 1 nm to approximately 25 nm.

In embodiments where the first semiconductor layers comprise silicon-germanium, the thickness of the first semiconductor layers 210 may depend on the germanium concentration of the first semiconductor layers 210. Typically, layers with higher germanium concentrations are less stable and therefore will be thinner relative to a layer of lower germanium concentration. In some embodiments, this thickness of the second semiconductor layers 220 may be approximately 1 nm to approximately 10 nm, preferably approximately 2 nm to approximately 5 nm. In embodiments where the first semiconductor layers 210 are made of silicon-germanium, the second semiconductor layers 220 may be formed of carbon-doped silicon and have a thickness such that the tensile strain of the carbon-doped silicon may compensate for some, most or all the compressive strain of the silicon-germanium, depending on the carbon concentration of the carbon-doped silicon and the germanium concentration of the silicon-germanium.

For example, a silicon-germanium fin with a height of 50 nm and a 50% germanium concentration may be desired. However, a 50 nm thick layer of 50% silicon-germanium may be relaxed and not exhibit the desired strain properties. Instead, a plurality of 5 nm thick layers of 50% silicon-germanium may be formed and separated by carbon-doped silicon layers to prevent relaxation. The thickness and carbon concentration of the carbon-doped silicon layers may be selected so that the tensile strain of the carbon-doped silicon compensates some strain of the oppositely strained silicon-germanium layers. In this example, a 4 nm thick carbon-doped silicon layer with 2% carbon may be chosen to compensate for some of the compressive strain of the 5 nm thick silicon-germanium layer with 50% germanium. Therefore, a 50 nm fin may be formed of alternating layers of 5 nm thick silicon-germanium layers with a germanium concentration of 50% (6 layers) and 4 nm thick carbon-doped silicon layers with a carbon concentration of 2% (5 layers).

In some embodiments, the first semiconductor layers 210 and the second semiconductor layers 220 may be formed by growing the layers on top of the preceding layer using typical epitaxial growth processes, such as chemical vapor deposition (CVD). For example, an epitaxial Si layer may be deposited from a silicon gas source such as disilane, trisilane, tetrasilane, hexachlorodisilane, tetrachlorosilane, dichlorosilane, trichlorosilane, methylsilane, dimethylsilane, ethylsilane, methyldisilane, dimethyldisilane, hexamethyldisilane or combinations thereof. An epitaxial silicon-germanium layer can be deposited by adding to the silicon gas source a germanium gas source such as germane, digermane, halogermane, dichlorogermane, trichlorogermane, tetrachlorogermane and combinations thereof. A carbon-doped silicon layer may be formed by adding a carbon gas source such as monomethylsilane to the silicon gas source. Carrier gases like hydrogen, nitrogen, helium and argon may be used.

Referring to FIGS. 3A-3C, the superlattice 200 may be etched to form a fin 250. The fin may be formed, for example, by etching the superlattice 200 by a photolithography process followed by an anisotropic etching process such as reactive ion etching (RIE) or plasma etching. Alternatively, a sidewall image transfer process may be used. The fin 250 may have a width of approximately 2 nm to approximately 100 nm, preferably approximately 4 nm to 40 approximately nm. In a preferred embodiment, the fins 250 may have a width in the range of approximately 6-15 nm. While the depicted embodiment includes only a single fin 250, a person of ordinary skill in the art will understand that additional embodiments may include multiple fins, either as a single FinFET device including multiple fins or as multiple single or multi-fin devices.

By forming the fin 250 from the superlattice 200, the fin may be made primarily of silicon-germanium (i.e., the second semiconductor layers 220) while not limiting the height of the fin 250 to the critical thickness of a silicon-germanium layer. Further, because the wave function of holes in the silicon-germanium of the second semiconductor layers 220 may extend several nanometers into the first semiconductor layers 210, the first semiconductor layers 210 may also contribute to current flow through the fin. Therefore, the total current flow through the fin 250 may be greater than a similar structure where a silicon-germanium fin is formed above a silicon dummy fin in order to obtain the necessary height.

Referring to FIGS. 4A-4C, a gate 300 may be formed over the fin 250. The gate 300 may include a gate dielectric 310 and a gate conductor 320 that can be formed via any known process in the art, including a gate-first process and a gate-last process. The gate 300 may also include a hard cap (not shown) made of an insulating material, such as, for example, silicon nitride, capable of protecting the gate electrode and gate dielectric during subsequent processing steps. The gate 300 may have a height of approximately 40 nm to approximately 200 nm, preferably approximately 50 nm to approximately 150 nm.

In a gate-first process, the gate dielectric 310 may include an insulating material including, but not limited to: oxide, nitride, oxynitride or silicate including metal silicates and nitrided metal silicates. In one embodiment, the gate dielectric 310 may include an oxide such as, for example, SiO₂, HfO₂, ZrO₂, Al₂O₃, TiO₂, La₂O₃, SrTiO₃, LaAlO₃, and mixtures thereof. The physical thickness of the gate dielectric 310 may vary, but typically may have a thickness ranging from approximately 0.5 nm to approximately 10 nm. The gate electrode 320 may be formed on top of the gate dielectric 310. The gate electrode 320 may be deposited by any suitable technique known in the art, for example by atomic layer deposition (ALD), chemical vapor deposition (CVD), physical vapor deposition (PVD), molecular beam deposition (MBD), pulsed laser deposition (PLD), or liquid source misted chemical deposition (LSMCD). The gate electrode 320 may include, for example, Zr, W, Ta, Hf, Ti, Al, Ru, Pa, metal oxides, metal carbides, metal nitrides, transition metal aluminides (e.g. Ti₃Al, ZrAl), TaC, TiC, TaMgC, or any combination of those materials. The gate electrode 320 may also include a silicon layer located on top of a metal material, whereby the top of the silicon layer may be silicided. The gate electrode 320 may have a thickness approximately of approximately 20 nm to approximately 100 nm and a width of approximately 10 nm to approximately 250 nm, although lesser and greater thicknesses and lengths may also be contemplated.

In a gate-last process, the gate dielectric 310 and the gate electrode 320 may be made of sacrificial materials to later be removed and replaced by a gate dielectric and a gate electrode such as those of the gate-first process described above. Sacrificial materials for the gate dielectric 310 may include, among others, silicon oxide. Sacrificial materials for the gate electrode 320 may include, among others, amorphous or polycrystalline silicon.

Referring to FIGS. 5A-5C, a spacer 410 may be formed on sidewalls of the gate 300. The spacer 410 may be made of , for example, silicon nitride, silicon oxide, silicon oxynitrides, or a combination thereof, and may be formed by any method known in the art, including depositing a conformal silicon nitride layer over the gate 300 and etching to remove unwanted material from the conformal silicon nitride layer. The spacer 410 may have a thickness of approximately 1 nm to approximately 10 nm. In some embodiments, the spacer 410 may have a thickness of approximately 1 nm to approximately 6 nm.

Referring to FIGS. 6A-6C, source/drain regions 510 may be formed on opposing ends of fin 250 (FIGS. 3B-3C) adjacent to the spacer 410. Source/drain regions 510 may be formed, for example, depositing or growing semiconductor material over the fin 250. In some embodiments, the exposed portions of the fin 250 may be removed. Further, a portion of the substrate 110 may be removed prior forming the source/drain regions 510. Additional methods of forming source/drain regions for FinFETs are known in the art and are not disclosed here. For pFinFETs such as the structure disclosed here, the source/drain regions 510 may be made of, for example, silicon or a silicon germanium-alloy, where the atomic concentration of germanium may range from about approximately 10% to approximately 80%, preferably from approximately 20% to approximately 60%. Dopants such as boron may be incorporated into the source/drain regions 510 by in-situ doping. The percentage of dopants may range from approximately 1×10¹⁹ cm⁻³ to approximately 2×10²¹ cm⁻³, preferably approximately 1×10²⁰ cm⁻³ to approximately 1×10²¹ cm⁻³.

The descriptions of the various embodiments of the present invention have been presented for purposes of illustration, but are not intended to be exhaustive or limited to the embodiments disclosed. Many modifications and variations will be apparent to those of ordinary skill in the art without departing from the scope and spirit of the described embodiments. The terminology used herein was chosen to best explain the principles of the embodiment, the practical application or technical improvement over technologies found in the marketplace, or to enable other of ordinary skill in the art to understand the embodiments disclosed herein. It is therefore intended that the present invention not be limited to the exact forms and details described and illustrated but fall within the scope of the appended claims.

What is claimed is:

1. A FinFET structure comprising:
a superlattice fin on a substrate, the superlattice fin comprising alternating layers of silicon-germanium and carbon-doped silicon;
a gate located over the superlattice fin; and
a source/drain region located adjacent to the superlattice fin.

2. The structure of claim 1, wherein the silicon-germanium layers have a germanium concentration ranging from approximately 10% to 80%.

3. The structure of claim 1, wherein the silicon-germanium layers have a thickness ranging from approximately 1 nm to approximately 25 nm.

4. The structure of claim 1, wherein the carbon-doped silicon layers have a carbon concentration ranging from approximately 0.2% to approximately 4%.

5. The structure of claim 1, wherein the carbon-doped silicon layers have a thickness ranging from approximately 1 nm to approximately 10 nm.

6. The structure of claim 1, wherein the superlattice fin comprises between 5 and 30 alternating layers.

7. The structure of claim 1, wherein the superlattice fin has a height ranging from approximately 5 nm to approximately 100 nm.

8. The structure of claim of claim 1, wherein the silicon-germanium layers are compressively strained and the carbon-doped silicon layers are tensilely strained.

9. A semiconductor structure comprising:
a superlattice fin located on a substrate, the superlattice fin comprising alternating layers of a first semiconductor material and a second semiconductor material, the first semiconductor material comprising silicon-germanium;
a gate located over the superlattice fin; and
a source/drain region located adjacent an end portion of the superlattice fin.

10. The structure of claim 9, wherein the second semiconductor material is carbon-doped silicon.

11. The structure of claim 10, wherein the second semiconductor material has a carbon concentration ranging from approximately 0.2% to approximately 4%.

12. The structure of claim 11, wherein the layers of the second semiconductor material have a thickness ranging from approximately 1 nm to approximately 10 nm.

13. The structure of claim 9, wherein the superlattice fin comprises 5 to 30 layers of the first semiconductor material and the second semiconductor material.

14. The structure of claim 9, wherein the superlattice fin has a height ranging from approximately 5 nm to approximately 100 nm.

15. A method of forming a semiconductor structure, the method comprising:
forming a superlattice of a first semiconductor material and a second semiconductor material, the first semiconductor material comprising silicon-germanium;
etching the superlattice to form a fin;
forming a gate over the fin; and
forming a source/drain region over a portion of the fin not covered by the gate.

16. The method of claim 15, wherein the second semiconductor material is carbon-doped silicon.

17. The structure of claim 16, wherein the second semiconductor material has a carbon concentration ranging from approximately 0.2% to approximately 4%.

18. The method of claim 16, wherein the layers of the second semiconductor material have a thickness ranging from approximately 1 nm to approximately 10 nm.

19. The method of claim 15, wherein the superlattice comprises 5 to 30 layers of the first semiconductor material and the second semiconductor material.

20. The structure of claim 15, wherein the fin has a height ranging from approximately 5 nm to approximately 100 nm.
